(19) United States
(12) Patent Application Publication
(10) Pub. No.: US 2025/0024738 A1
(43) Pub. Date: Jan. 16, 2025

(54) ELECTRO-OPTICAL DEVICE AND ELECTRONIC DEVICE

(71) Applicant: SEIKO EPSON CORPORATION, Tokyo (JP)

(72) Inventor: Yuiga HAMADE, MATSUMOTO-SHI (JP)

(73) Assignee: SEIKO EPSON CORPORATION, Tokyo (JP)

(21) Appl. No.: 18/766,667

(22) Filed: Jul. 9, 2024

(30) Foreign Application Priority Data
Jul. 11, 2023 (JP) 2023-113953

(51) Int. Cl. H10K 59/80; H10K 102/00

(52) U.S. Cl. CPC H10K 59/878; H10K 59/80518; H10K 2102/351

(57) ABSTRACT

An electro-optical device includes reflective electrodes having light reflectivity and being adjacent to each other along an X direction, pixel electrodes being formed of TiN and being adjacent to each other along the X direction, an optical adjustment layer, a pixel separation layer opening in an opening portion Ap_R with respect to the pixel electrode and opening in an opening portion Ap_G with respect to the pixel electrode, a common electrode, and an organic layer being provided between the common electrode and the pixel electrode. An end P₁ of the opening portion Ap_R, an end P₂ of the reflective electrode, and an end P₃ of the pixel electrode are positioned in the stated order along the X direction, and an end P₄ of the opening portion Ap_G, an end P₅ of the reflective electrode, and an end P₆ of the pixel electrode are positioned in the stated order along a direction opposite to the X direction.

The present application is based on, and claims priority from JP Application Serial Number 2023-113953, filed Jul. 11, 2023, the disclosure of which is hereby incorporated by reference herein in its entirety.

### BACKGROUND

### 1. Technical Field

The present disclosure relates to an electro-optical device and an electronic apparatus.

### 2. Related Art

In an electro-optical device using an OLED as a light emitting element, for example, there has been known a technique of using a white light emitting element to achieve color display and enhancing and extracting light having a specific wavelength by a light resonance structure in a pixel portion corresponding to red, green, or blue (for example, see JP-A-2022-100348).

However, in the technique described in JP-A-2022-100348, there is a problem that a phenomenon where a pixel electrode opens with respect to an insulating layer and emits light in a periphery of a region adjacent to a light emitting layer, in other words, peripheral light emission is observed.

### SUMMARY

According to one aspect of the present disclosure, an electro-optical device includes a first reflection layer and a second reflection layer having light reflectivity and being adjacent to each other along a first direction in plan view, a first pixel electrode and a second pixel electrode being formed of a metal nitride and being adjacent to each other along the first direction in plan view, a first optical adjustment layer having an insulating property and optical transparency and being provided between the first reflection layer and the first pixel electrode, a second optical adjustment layer having an insulating property and optical transparency and being provided between the second reflection layer and the second pixel electrode, an insulating layer opening in a first opening portion to the first pixel electrode in plan view and opening in a second portion to the second pixel electrode in plan view, a common electrode, and an organic layer being provided between the common electrode, and the insulating layer, the first pixel electrode, or the second pixel electrode, and including a light emitting layer, wherein, in plan view, an end of ends of the first opening portion that is adjacent to the second opening portion is a first end, an end of ends of the first reflection layer that is adjacent to the second reflection layer is a second end, an end of ends of the first pixel electrode that is adjacent to the second pixel electrode is a third end, an end of ends of the second opening portion that is adjacent to the first opening portion is a fourth end, an end of ends of the second reflection layer that is adjacent to the first reflection layer is a fifth end, and an end of ends of the second pixel electrode that is adjacent to the first pixel electrode is a sixth end, the first end, the second end, and the third end are positioned in the stated order along the first direction from the first opening portion to the second opening portion, and the fourth end, the fifth end, and the sixth end are positioned in the stated order along the first direction from the second opening portion to the first opening portion.

### BRIEF DESCRIPTION OF THE DRAWINGS

FIG. 1 is a view illustrating a configuration of an electro-optical device according to an embodiment.

FIG. 2 is a block diagram illustrating an electrical configuration of the electro-optical device.

FIG. 3 is a circuit diagram illustrating a pixel portion in the electro-optical device.

FIG. 4 is a timing chart illustrating an operation of the electro-optical device.

FIG. 5 is a plan view illustrating pixel portions in the electro-optical device.

FIG. 6 is a cross-sectional view illustrating main parts of a reflection layer and a pixel electrode in the electro-optical device.

FIG. 7 is a cross-sectional view illustrating the main parts of the reflection layer and the pixel electrode in the electro-optical device.

FIG. 8 is a cross-sectional view illustrating the main parts of the reflection layer and the pixel electrode in the electro-optical device.

FIG. 9 is a cross-sectional view illustrating main parts of a reflection layer and a pixel electrode in a first comparative example.

FIG. 10 is a cross-sectional view illustrating main parts of a pixel portion.

FIG. 11 is a cross-sectional view illustrating the main parts of the pixel portion.

FIG. 12 is a cross-sectional view illustrating main parts of a pixel portion in a second comparative example.

FIG. 13 is a cross-sectional view illustrating main parts of a pixel portion in a third comparative example.

FIG. 14 is a view illustrating comparison between the embodiment and the third comparative example.

FIG. 15 is a view illustrating comparison between the embodiment and the third comparative example.

FIG. 16 is a perspective view illustrating a head-mounted display using the electro-optical device.

FIG. 17 is a view illustrating an optical configuration of the head-mounted display.

### DESCRIPTION OF EMBODIMENTS

An electro-optical device according to an embodiment of the present disclosure will be described below with reference to the accompanying drawings. In each of the drawings, dimensions and scale of each part are appropriately different from actual ones. Moreover, the embodiment described below is a suitable specific example, and various technically preferable limitations are applied, but the scope of the disclosure is not limited to these modes unless they are specifically described in the following description as limiting the disclosure.

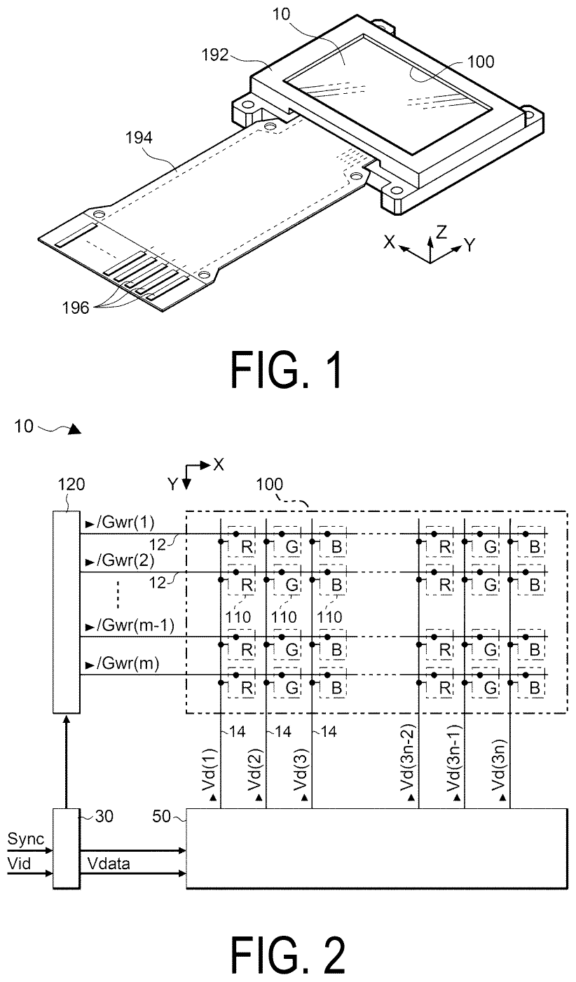

FIG. 1 is a perspective view illustrating an electro-optical device 10 according to an embodiment, and FIG. 2 is a block diagram illustrating an electrical configuration of the electro-optical device 10.

The electro-optical device 10 is a micro display panel that displays a color image, for example, in a head-mounted display (HMD) or the like. The electro-optical device 10 includes a plurality of pixel portions, a drive circuit that drives the pixel portions, and the like. The pixel portions and the drive circuit are integrated into a semiconductor substrate. The semiconductor substrate is typically a silicon substrate, but may be a different semiconductor substrate.

The electro-optical device 10 is accommodated in a frame-shaped case 192 that opens in a display region 100. One end of an FPC substrate 194 is coupled to the electro-optical device 10. FPC is an abbreviation for flexible printed circuit. The other end of the FPC substrate 194 is provided with a plurality of terminals 196 for coupling a host device, which is omitted in illustration. When the plurality of terminals 196 are coupled to the host device, video data, synchronization signals, and the like are supplied from the host device to the electro-optical device 10 via the FPC substrate 194.

In the drawings, an X direction is an extension direction of a scanning line in the electro-optical device 10 and indicates a transverse direction on a display screen, and a Y direction is an extension direction of a data line and indicates a longitudinal direction on the display screen. A two-dimensional plane defined in the X direction and the Y direction is a substrate surface of a semiconductor substrate. A Z direction is perpendicular to the X direction and the Y direction, and is an emission direction of light emitted from a light emitting element. Further, in the description, in plan view, the semiconductor substrate is seen in a direction opposite to the Z direction, and in a cross-sectional view, the semiconductor substrate is seen in a state in which the semiconductor substrate is cut in a vertical direction of a substrate surface.

As illustrated in FIG. 2, the electro-optical device 10 is substantially divided into a control circuit 30, a data signal output circuit 50, a display region 100, and a scanning line drive circuit 120.

In the display region 100, scanning lines 12 of m rows are provided in the X direction, and data lines 14 of (3n) columns are provided in the Y direction to be electrically insulated from each of the scanning lines 12. Each of m and n is an integer equal to or greater than 2.

In the display region 100, pixel portions 110 are provided corresponding to intersections between the scanning lines 12 of the m rows and the data lines 14 of the (3n) columns. Thus, the pixel portions 110 are arranged in a matrix of m longitudinal rows×(3n) horizontal columns. To distinguish the rows from each other in the array of the matrix, the rows may be referred to as first, second, third, . . . , (m−1)-th, and m-th rows in order from the top in the drawing. Similarly, to distinguish the columns from each other in the matrix, the columns may be referred to as first, second, third, . . . , (3n−2), (3n−1)-th, and (3N)-th columns in order from the left in the drawing.

Integers i from 1 to m are used to generalize and explain the scanning lines 12. Similarly, in order to generalize and explain the data lines 14, an integer j of 1 or more and (3n) or less is used.

The control circuit 30 controls each portion based on video data Vid and a synchronization signal Sync supplied from the high-order host device, which is omitted in illustration. Specifically, the control circuit 30 generates various control signals to control each portion.

The video data Vid designates, for example, a gradation level of a pixel in an image to be displayed by 8 bits. The synchronization signal Sync includes a vertical synchronization signal for giving an instruction for starting vertical scanning of the video data Vid, a horizontal synchronization signal for giving an instruction for starting horizontal scanning, and a dot clock signal that indicates a timing of one pixel of the video data.

Pixels of an image to be displayed in the present embodiment and the pixel portions 110 in the display region 100 correspond one-to-one with each other.

Characteristics of a luminance at a gradation level indicated by video data Vid supplied from the host device and characteristics of a luminance in the OLED included in the pixel portion 110 do not necessarily match with each other. Thus, to make the OLED emit light at a luminance corresponding to the gradation level indicated by the video data Vid, the control circuit 30 up-converts 8 bits of the video data Vid into, for example, 10 bits and outputs it as video data Vdata. Thus, the 10-bit video data Vdata is data corresponding to the gradation level designated by the video data Vid.

A look-up table is used for the up-conversion, the look-up table being a table in which a correspondence relationship between the 8 bits of the video data Vid which is an input and the 10 bits of the video data Vdata which is an output is stored in advance.

The scanning line drive circuit 120 is a circuit for driving the pixel portions 110 arranged in m rows and (3n) columns for each row corresponding to control by the control circuit 30. For example, the scanning line drive circuit 120 supplies scanning signals /Gwr(1), /Gwr(2) . . . /Gwr(m−1), /Gwr(m) to the scanning lines 12 in the first, second, third . . . (m−1)-th, and m-th rows in order. To generalize, the scanning signal supplied to the scanning line 12 of the i-th row is denoted as /Gwr(i).

The data signal output circuit 50 is a circuit that outputs a data signal to the pixel portions 110 located in a row selected by the scanning line drive circuit 120 via the data line 14 corresponding to the control of the control circuit 30. The data signal is a voltage signal that converts the 10-bit video data Vdata into an analog type. In other words, the data signal output circuit 50 converts video data Vdata of one row corresponding to the pixel portions 110 of first to (3n)-th columns in the selected row into an analog type and outputs the analog type data to the data lines 14 of the first to (3n)-th columns in order.

In the drawing, the data signals output to the data lines 14 of the first, second, third, . . . , (3n−2)-th, (3n−1)-th, and (3n)-th columns are referred to as Vd(1), Vd(2), Vd(3), . . . , Vd(3n−2), Vd(3n−1), and Vd(3n). To generalize, the potential of the data line 14 of the j-th column is denoted as Vd(j).

As illustrated in FIG. 2, in the pixel portions 110 of the display region 100, from an electrical point of view, the pixel portions 110 of R, the pixel portions 110 of B, and the pixel portions 110 of G are arranged in the X direction, and the pixel portions 110 of the same color are arranged in the Y direction. Thus, focusing on some data lines 14 in one column, the pixel portions 110 of the same color correspond to each other. One color is expressed by an additive color mixture of the pixel portions 110 of the RBG adjacent to each other in the X direction. Thus, the pixel portion 110 should be referred to as a sub-pixel portion in a strict sense, but for convenience of explanation, the pixel portion 110 is designated as a pixel portion.

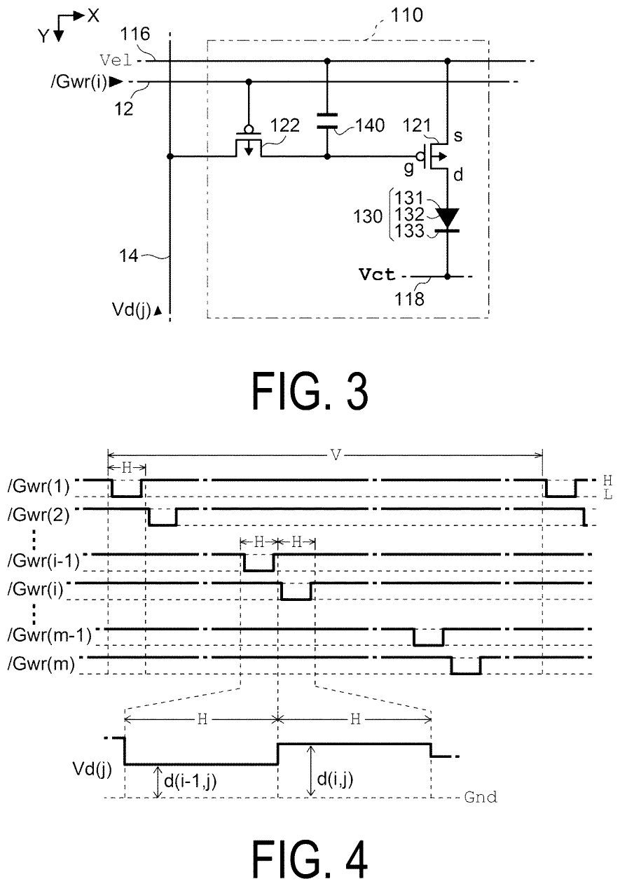

FIG. 3 is a view illustrating an electrical configuration of the pixel portion 110 in the electro-optical device 10. The pixel portions 110 arranged in 1080 rows and (3n) columns are identical to each other from the electrical point of view. Therefore, the pixel portion 110 will be described with one pixel portion 110 corresponding to an i-th row and a j-th column as a representative.

As illustrated in the drawing, the pixel portion 110 includes P-channel MOS type transistors 121 and 122, an OLED 130, and a capacitive element 140 from the electrical point of view.

In the description of the pixel portion 110, the “electrical point of view” is used when a plurality of elements constituting the pixel portion 110 and a coupling relationship between the plurality of elements are referred to. Since the pixel portion 110 includes elements that do not contribute to the electrical coupling relationship from a mechanical or physical point of view, such an expression is used.

The OLED 130 is an example of a light emitting element, and an organic layer 132 including a light emitting layer is sandwiched between the pixel electrode 131 and the common electrode 133. The pixel electrode 131 serves as an anode, and the common electrode 133 serves as a cathode. The details of the OLED 130 are described later, and when a current flows from the anode to the cathode, holes injected from the anode and electrons injected from the cathode are recombined in the light emitting layer of the organic layer 132 to generate excitons, and white light is generated.

The generated white light resonates in an optical resonator configured by a reflective electrode, which is omitted in FIG. 3, and the common electrode 133 of a semi-reflective and semi-transmissive layer and is emitted at a resonance wavelength set corresponding to any of red, green, and blue. A color filter corresponding to the color is provided on the emission side of the light emitted from the optical resonator. Thus, the emitted light from the OLED 130 is visually recognized by an observer through coloration by the optical resonator and the color filter.

In the transistor 121 of the pixel portion 110 in the i-th row and the j-th column, a gate node g is coupled to a drain node of the transistor 122, a source node is coupled to a feed line 116 of a voltage Vel, and a drain node is coupled to the pixel electrode 131 which is an anode of the OLED 130.

In the transistor 122 of the pixel portion 110 in the i-th row and the j-th column, a gate node is coupled to the scanning line 12 of the i-th row, and a source node is coupled to the data line 14 of the j-th column. The common electrode 133, which functions as a cathode of the OLED 130, is coupled to a power supplying line 118 of a voltage Vct. Further, since the electro-optical device 10 is formed on a silicon substrate, a substrate potential of each of the transistors 121 and 122 is set to a potential corresponding to, for example, the voltage Vel.

Because the pixel portion 110 illustrated in FIG. 3 is common to each of red, green, and blue from the electrical point of view, it will be generally described without identifying the color, but it is different for each color from a structural point of view. Therefore, when the colors are described separately, the pixel portion 110 is referred to as pixel portions 110R, 110G, and 110B. Similarly, when the OLED 130 and the pixel electrode 131 are described separately by color, the OLED 130 is referred to as OLEDs 130R, 130G, and 130B and the pixel electrode 131 is referred to as pixel electrodes 131R, 131G, and 131B.

FIG. 4 is a timing chart for describing an operation of the electro-optical device 10.

In the electro-optical device 10, the scanning lines 12 of m rows are scanned one by one in the order of first, second, third . . . m-th rows during a period of a frame (V). Specifically, as illustrated in the drawing, the scanning signals /Gwr(1), /Gwr(2) . . . /Gwr(m−1), and /Gwr(m) successively and exclusively reach an L level for each horizontal scanning period (H) by the scanning line drive circuit 120.

Note that, in the present embodiment, a period during which the adjacent scanning signals among the scanning signals /Gwr(1) to /Gwr(m) reach the L level is temporally isolated. Specifically, after the scanning signal /Gwr(i−1) changes from the L level to an H level, the next scanning signal /Gwr(i) reaches the L level after a period of time. This period corresponds to a horizontal return period.

In this description, the period of one frame (V) refers to a period required to display one frame of an image designated by the video data Vid. In a case in which a length of the period of one frame (V) is the same as a vertical synchronization period, for example, when a frequency of a vertical synchronization signal included in the synchronization signal Sync is 60 Hz, it is 16.7 milliseconds, which corresponds to one cycle of the vertical synchronization signal. Further, the horizontal scanning period (H) is an interval of time in which the scanning signals /Gwr(1) to /Gwr(m) reach the L level in order, but in the drawing, for convenience, a start timing of the horizontal scanning period (H) is approximately a center of the horizontal return period.

When a certain scanning signal among the scanning signals /Gwr(1) to /Gwr(m), for example, the scanning signal /Gwr(i) supplied to the scanning line 12 in the i-th row reaches the L level, the transistor 122 in the pixel portion 110 of the i-th row and the j-th column, speaking of the j-th column, is in an ON state. Thus, the gate node g of the transistor 121 in the pixel portion 110 is electrically coupled to the data line 14 of the j-th column.

In the present description, the “On state” of the transistor indicates that a distance between the source node and the drain node in the transistor is electrically closed to be in a low impedance state. Also, an “OFF state” of the transistor indicates that the distance between the source node and the drain node electrically opens to be in a high impedance state.

Further, in this description, “electrically coupled” or simply “coupled” means a state in which two or more elements are directly or indirectly coupled or joined. “Electrically non-coupled” or simply “non-coupled” means a state in which two or more elements are not directly or indirectly coupled or joined.

In the horizontal scanning period (H) in which the scanning signal /Gwr(i) reaches the L level, the data signal output circuit 50 converts the gradation levels of pixels in the i-th row and first column to the i-th row and n-th column indicated by the video data Vdata into analog potentials Vd(1) to Vd(n), and outputs the analog potentials Vd(1) to Vd(n) to the data signals 14 in the first to n-th columns as data signals. In the j-th column, the data signal output circuit 50 converts the gradation level d (i, j) of the pixel in the i-th row and j-th column into the potential Vd(j) of the analog signal, and outputs the potential Vd(j) to the data line 14 in the j-th column.

In the horizontal scanning period (H) in which the scanning signal /Gwr(i−1) one line before the scanning signal /Gwr(i) reaches the L level, the data signal output circuit 50 converts the gradation level d(i−1, j) of the pixel in the (i−1)-th row and j-th column to the potential Vd(j) of the analog signal, and outputs the potential Vd(j) to the data signal 14 in the j-th column as a data signal.

The data signal of the potential Vd (j) is applied to the gate node g of the transistor 121 in the pixel portion 110 in the i-th row and j-th column via the data line 14 in the j-th column, and the potential Vd (j) is retained by the capacitive element 140. Therefore, the transistor 121 causes a current corresponding to a voltage between the gate node and the source node to flow to the OLED 130.

Even when the scanning signal Gwr(i) reaches the H level and the transistor 122 is in the OFF state, the potential Vd(j) is retained by the capacitive element 140, and thus the current continues to flow in the OLED 130. Thus, in the pixel portion 110 in the i-th row and j-th column, the OLED 130 continues to emit light with a voltage retained by the capacitive element 140, in other words, a luminance corresponding to the gradation level until the period of one frame (V) elapses and the transistor 122 is turned on again and the voltage of the data signal is applied again.

Although the pixel portion 110 of the i-th row and j-th column has been described here, the OLED 130 of the pixel portion 110 other than the j-th column in the i-th row also emits light at the luminance indicated by the video data Vdata.

Also, the OLED 130 of the pixel portion 110 other than the i-th row also emits light with the luminance indicated by the video data Vdata by the scanning signals /Gwr(1) to /Gwr(m) reaching the L level in order.

Thus, in the electro-optical device 10, during the period of one frame (V), the OLED 130 in all of the pixel portions 110 from the first row and first column to the m-th row and n-th column emits light at the luminance indicated by the video data Vdata, and an image of one frame is displayed.

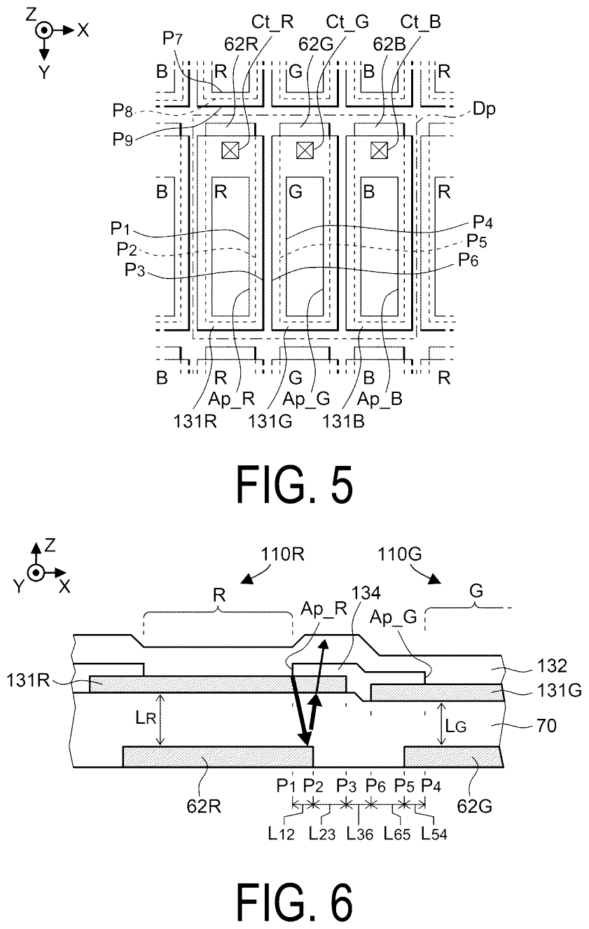

FIG. 5 is a view illustrating an arrangement of the pixel portions 110 in the display region 100. A color of one dot in the display region 100 is represented by an additive color mixture of emitted light from three light emitting regions surrounded by a frame Dp in the drawing. Specifically, in the frame Dp, the light emitting regions R, G, and B are arranged in the stated order along the X direction.

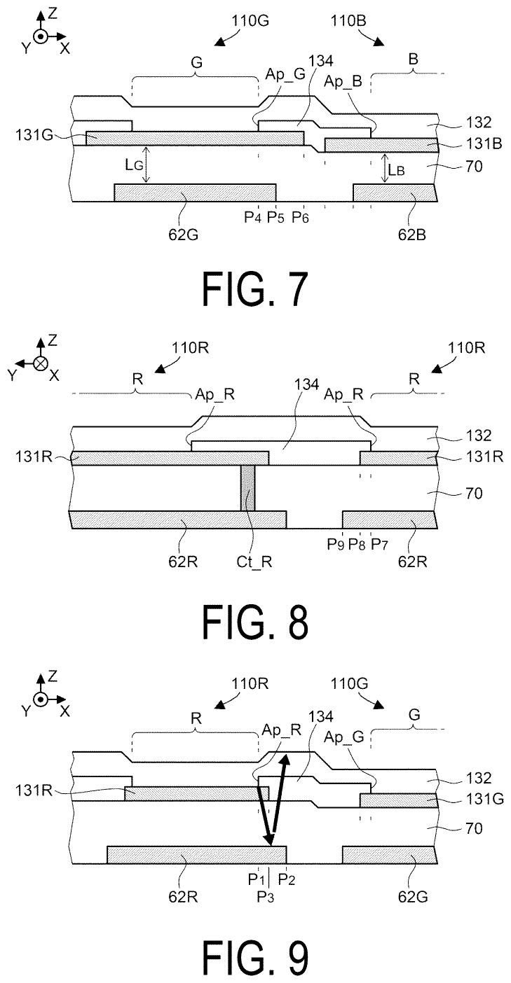

FIG. 6 is a cross-sectional view illustrating main parts of a region including the pixel portion 110R and a part of the pixel portion 110G, which is taken along the X direction, and FIG. 7 is a cross-sectional view illustrating main parts of a region including the pixel portion 110G and a part of the pixel portion 110B, which is taken along the X direction. Further, FIG. 8 is a cross-sectional view illustrating main parts of a region including the two pixel portions 110R adjacent to each other, which is taken along the Y direction.

In the pixel portion 110R, a reflective electrode 62R, an optical adjustment layer 70, the pixel electrode 131R, the pixel separation layer 134, and the organic layer 132 are stacked in the stated order.

The reflective electrode 62R is a conductive electrode that is subjected to patterning to have a rectangular shape corresponding to the pixel portion 110R as illustrated in FIG. 5 and has light reflectivity, and reflects light, which is incident in a direction opposite to the Z direction, in the Z direction. As the reflective electrode 62R, for example, a conductive layer in which an alloy (AlCu) film of aluminum and copper is layered on a titanium (Ti) film is used.

The optical adjustment layer 70 is a stacking body of insulating layers having transparency, such as silicon oxide (SiO₂) and silicon nitride (SiN). The thickness of the optical adjustment layer 70 differs in the pixel portions 110R, 110G, and 110B as described later. In the pixel portion 110R, the thickness of the optical adjustment layer 70 between the reflective electrode 62R and the pixel electrode 131R is L_{R}. In the description, a thickness of a layer or an electrode refers to a distance along the Z direction in a cross-sectional view.

In the present embodiment, the pixel electrode 131R is a conductive electrode obtained by subjecting titanium nitride (TiN) having optical transparency and light reflectivity to patterning to have a rectangular shape as illustrated in FIG. 5.

As illustrated in FIG. 5 and FIG. 8, the pixel electrode 131R is electrically coupled to the reflective electrode 62R via a contact hole Ct_R. Further, the reflective electrode 62R is electrically coupled to the drain node of the transistor 121 via another contact hole, which is omitted in illustration.

The pixel separation layer 134 is an insulating film that is stacked on the optical adjustment layer 70 and the pixel electrode 131R, is provided to cover the peripheral edge portion of the pixel electrode 131R, and has optical transparency. In the pixel portion 110R, the pixel separation layer 134 has an opening Ap_R in the shape illustrated in FIG. 5 in plan view. For example, silicon oxide is used as the pixel separation layer 134.

The organic layer 132 is stacked on the pixel electrode 131R or the pixel separation layer 134. As described later, the organic layer 132 includes a hole injection layer, a light emitting layer, an electron transporting layer, and the like, and is common in all the pixel portions including the pixel portions 110R, 110G, and 110B.

Similarly to the pixel portion 110R, in the pixel portion 110G, a reflective electrode 62G, the optical adjustment layer 70, the pixel electrode 131G, the pixel separation layer 134, and the organic layer 132 are stacked in the stated order. However, the thickness L_{G} of the optical adjustment layer 70 in the pixel portion 110G is smaller than the thickness L_{R} of the optical adjustment layer 70 in the pixel portion 110R.

Similarly to the pixel portions 110R and 110G, in the pixel portion 110B, a reflective electrode 62B, the optical adjustment layer 70, the pixel electrode 131B, the pixel separation layer 134, and the organic layer 132 are stacked in the stated order. However, the thickness L_{b} of the optical adjustment layer 70 in the pixel portion 110B is smaller than the thickness L_{G} of the optical adjustment layer 70 in the pixel portion 110G.

In other words, the thicknesses of the optical adjustment layer 70 satisfy L_{R}>L_{G}>L_{B}. Specific numerical values and the like of the thicknesses L_{R}, L_{G}, and L_{B} of the optical adjustment layer 70 are described later.

Note that, although omitted in FIG. 6, FIG. 7, and FIG. 8, a drive circuit and the like are formed below the reflective electrodes 62R, 62G, and 62B, and the common electrode 133, a sealing layer, a color filter, protection glass, and the like are formed above the organic layer 132.

As illustrated in FIG. 6, an end of the opening Ap_R in the pixel portion 110R, which is close to the pixel portion 110G adjacent thereto in the X direction, is P₁. Further, an end of the reflective electrode 62R in the pixel portion 110R, which is close to the pixel portion 110G, is P₂, and an end of the pixel electrode 131R in the pixel portion 110R, which is close to the pixel portion 110G, is P₃. The ends P₁, P₂, and P₃ are positioned in the stated order along the X direction in plan view.

In a direction opposite to the X direction, an end of the opening Ap_R, an end of the reflective electrode 62R, and an end of the pixel electrode 131R are also positioned in the stated order in plan view.

Further, as illustrated in FIG. 8, an end of the opening Ap_R in the pixel portion 110R, which is close to the pixel portion 110R of the same color being adjacent thereto in the Y direction, is P₇. Further, an end of the reflective electrode 62R in the pixel portion 110R, which is close to the pixel portion 110G, is P₈, and an end of the pixel electrode 131R in the pixel portion 110R, which is close to the pixel portion 110R adjacent thereto in the Y direction, is P₉. The ends P₇, P₈, and P₉ are positioned in the stated order along the Y direction in plan view.

As illustrated in FIG. 5, in plan view, the opening Ap_R is included in the reflective electrode 62R. Further, the reflective electrode 62R is included in the pixel electrode 131R, except for a side positioned in a direction opposite to the Y direction in the drawing.

Description is made on a first comparison example with respect to the embodiment to describe an effect of the embodiment adopting such a positional relationship.

FIG. 9 is a cross-sectional view illustrating main parts of a region including the pixel portion 110R and a part of the pixel portion 110G in an electro-optical device in the first comparison example, which is taken along the X direction.

In the first comparison example, the end P₁ of the opening Ap_R, the end P₂ of the reflective electrode 62R, and the end P₃ of the pixel electrode 131R in the pixel portion 110R are positioned in the order of the end P₁, P₃, and P₂ along the X direction in plan view, which is different from the embodiment. In other words, in the first comparison example, in plan view, the opening Ap_R is included in the pixel electrode 131R, and the pixel electrode 131R is included in the reflective electrode 62R.

As indicated with the arrows in FIG. 9, in the first comparison example, of light emitted from the organic layer 132 near the end P₁ of the opening Ap_R, light incident in an oblique direction with respect to a direction opposite to the Z direction passes through the pixel electrode 131R, is reflected at the reflective electrode 62R, passes outside of the opening Ap_R, and is emitted. In a light resonance structure, an optical path length increases as light has a longer wavelength. Thus, in particular, peripheral light emission is more likely to occur, where a user visually recognizes red light passing through and being emitted from a region other than the opening Ap_R.

In contrast, in the present embodiment, as indicated with the arrows in FIG. 6, of light emitted from the organic layer 132 near the end P₁ of the opening Ap_R, light incident in an oblique direction with respect to a direction opposite to the Z direction passes through the pixel electrode 131R, is reflected at the reflective electrode 62R, and passes through the pixel electrode 131R again. When the reflection light from the reflective electrode 62R passes through the pixel electrode 131R again, it is attenuated. Thus, peripheral light emission is suppressed.

Herein, description is made while focusing on the pixel portion 110R. Similarly to the pixel portion 110R, in the pixel portion 110G of the green color and the pixel portion 110B of the blue color, peripheral light emission caused by light that is reflected in an oblique direction to be visually recognized can be suppressed.

In the embodiment, a width L₂₃ between the ends P₂ and P₃ along the X direction may be larger than a width L₁₂ between the end P₁ and P₂. With this configuration, as compared to a configuration in which the width L₂₃ is equal to or smaller than the width Lie, the oblique light reflected at the reflective electrode 62R is absorbed more by the pixel electrode 131R. Thus, peripheral light emission can be suppressed more.

A width refers to a distance between two points along a specific direction.

Further, in the embodiment, the width L₂₃ between the ends P₂ and P₃ along the X direction may be larger than the width L₁₂ between the ends P₁ and P₂ along the X direction. With this configuration, as compared to a configuration in which the width between the ends P₂ and P₃ is equal to or smaller than the width between the ends P₁ and P₂, the oblique light reflected at the reflective electrode 62R is absorbed more by the pixel electrode 131R. Thus, peripheral light emission can be suppressed more.

Further, in the embodiment, the width L₂₃ between the end P₂ and P₃ along the X direction may be larger than a width L₃₆ between the end P₃ and P₆ along the X direction, in other words, the width of the interval between the pixel electrodes 131R adjacent to each other along the X direction. With this configuration, as compared to a configuration in which the width L₂₃ is equal to or smaller than the width L₃₆, the oblique light reflected at the reflective electrode 62R is absorbed more by the pixel electrode 131R. Thus, peripheral light emission can be suppressed more.

Titanium nitride used for the pixel electrodes 131R, 131G, and 131B has reflectivity and absorbance of light. Thus, the film thickness may be as small as possible, specifically, may be equal to or larger than 5 nm and smaller than 20 nm.

In the peripheries of the openings Ap_R, Ap_G, and Ap_B, steps are present to some extent due to another element, for example, a contact hole or the like. When light is emitted at a step, an optical path length is longer than a design value. As a result, an emission light component having a long wavelength is easily emitted to the outside. For example, when peripheral light emission occurs in the pixel portion 130G of the green color, light close to red is generated.

Titanium nitride used for the pixel electrodes 131R, 131G, and 131B has high reflectivity and absorbance of light on a long wavelength side. Thus, titanium nitride is provided more widely than the openings Ap_R, Ap_G, and Ap_B in plan view, and hence peripheral light emission can be suppressed.

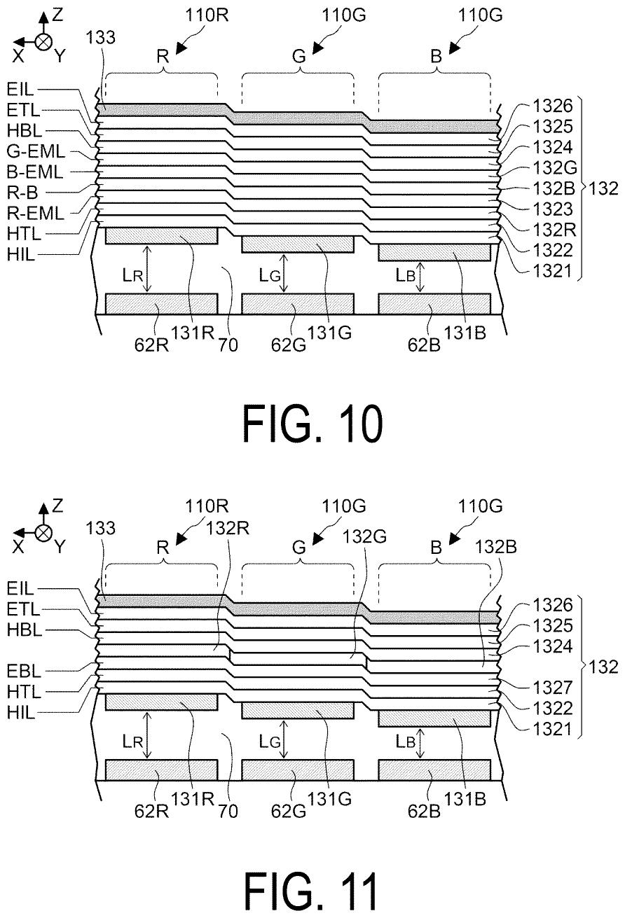

FIG. 10 is a cross-sectional view illustrating main parts of a configuration from the reflective electrode to the common electrode in the present embodiment, in particular, a detailed configuration of the organic layer.

The optical adjustment layer 70 stacked on the reflective electrodes 62R, 62G, and 62B is provided to have the different thicknesses L_{R}, L_{G}, and L_{B} for the respective colors, as described above. The organic layer 132 is provided between the pixel electrode 131R, 131G, or 131B and the common electrode 133.

The organic layer 132 includes the following layers. Specifically, the organic layer 132 includes a configuration in which a hole injection layer (HIL) 1321, a hole transporting layer (HTL) 1322, a red light emitting layer (R-EML) 132R, an intermediate layer 1323, a blue light emitting layer (B-EML) 132B, a green light emitting layer (G-EML) 132G, a hole blocking layer (HBL) 1324, an electron transporting layer (ETL) 1325, and an electron injection layer (EIL) 1326 are stacked in the stated order.

FIG. 10 illustrates a configuration of generating white light, but the configuration may be a configuration in which the red light emitting layer 132R, the green light emitting layer 132G, and the blue light emitting layer 132B are provided in the pixel portions 130R, 130G, and 130B, respectively, as illustrated in FIG. 11.

With this configuration, the red light emitting layer 132R, the green light emitting layer 132G, and the blue light emitting layer 132B are provided to the respective colors (sub pixels). Thus, as compared to the configuration in which three light emitting layers are stacked, in other words, the configuration illustrated in FIG. 10, reduction of power consumption can be achieved.

In FIG. 11, an electron blocking layer (EBL) 1327 is provided between the red light emitting layer 132R, the green light emitting layer 132G, or the blue light emitting layer 132B and the hole transporting layer 1322. Further, in FIG. 10 and FIG. 11, the pixel separation layer 134 is omitted.

With reference to comparison with a second comparative example, description is made on the superiority of the present embodiment adopting a light resonance structure in which the thickness differs for each color.

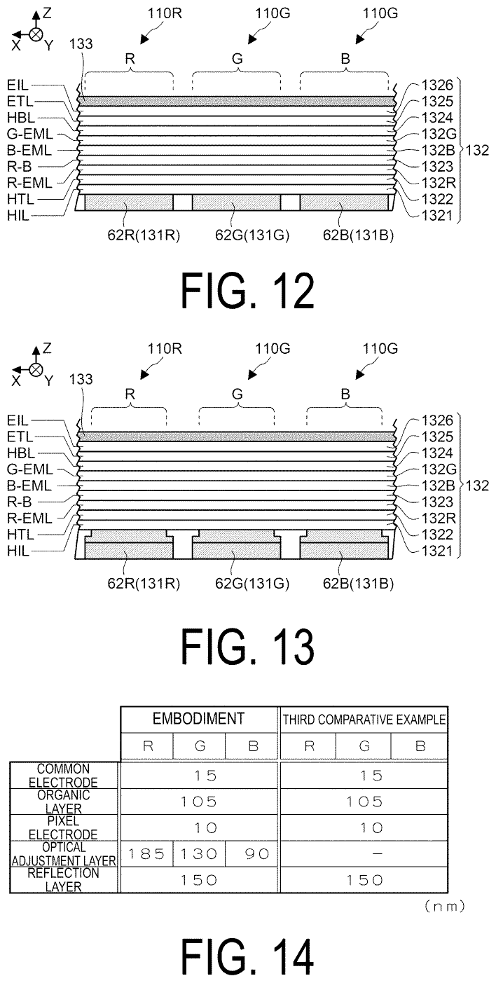

FIG. 12 is a cross-sectional view illustrating main parts of a configuration of an electro-optical device in the second comparative example.

In the second comparative example, the organic layer 132 has the layer structure as that of the organic layer 132 according to the embodiment. However, the optical adjustment layer 70 is not provided, and the reflective electrode 62R also functions as the pixel electrode 131R. Similarly, in the second comparative example, the reflective electrode 62G also functions as the pixel electrode 131G, and the reflective electrode 62B also functions as the pixel electrode 131B.

In the second comparative example, in a case of the pixel portion 110R of the red color, light emitted from the organic layer 132 is reflected at the reflective electrode 62R, and part of the reflection light passes through the common electrode 133, and is visually recognized by a user. On the other hand, the remaining part of the reflection light is reflected at the common electrode 133, and advances toward the reflective electrode 62R. However, in the second comparative example, the distance between the reflective electrode 62R, 62G, or 62B and the common electrode 133 is constant for each color. As a result, resonance does not occur according to an optical path length, and light extraction efficiency is degraded.

Moreover, a natural oxide film having a thickness of several nanometers is formed at the surface of the reflective electrodes 62R, 62G, and 62B containing aluminum as a main component. Thus, charges are less likely to be injected from the anode. Thus, in order to secure the required luminance, a driving voltage of the OLED 130 is required to be increased. However, in a micro display panel, in order to achieve pixel miniaturization, the voltage resistance of the transistor 122 is limited. As a result, the OLED 130 cannot be driven by a high voltage. Therefore, in the second comparative example, the maximum luminance of the micro display panel is reduced.

In order to prevent formation of a natural oxide film at the surfaces of the reflective electrodes 62R, 62G, and 62B, it is also conceivable to provide a configuration in which a conductive film 63 (for example, titanium nitride) having conductivity is provided between the reflective electrodes 62R, 62G, and 62B and the hole injection layer 1321, as illustrated in FIG. 13. The configuration is a third comparative example. However, in the third comparative example, due to presence of the conductive film 63 having conductivity, reflectivity at the reflective electrodes 62R, 62G, and 62B is reduced. Thus, light extraction efficiency is further degraded as compared to the second comparative example.

The present embodiment adopts a resonance structure in which light emitted from the organic layer 132 is repeatedly reflected between the reflective electrode 62R, 62G, or 62B and the common electrode 133. An optical distance in a resonance structure can be adjusted by the thicknesses L_{R}, L_{G}, and L_{B} of the optical adjustment layer 70 for R, G, and B, respectively. Thus, light extraction efficiency according to a wavelength can be improved.

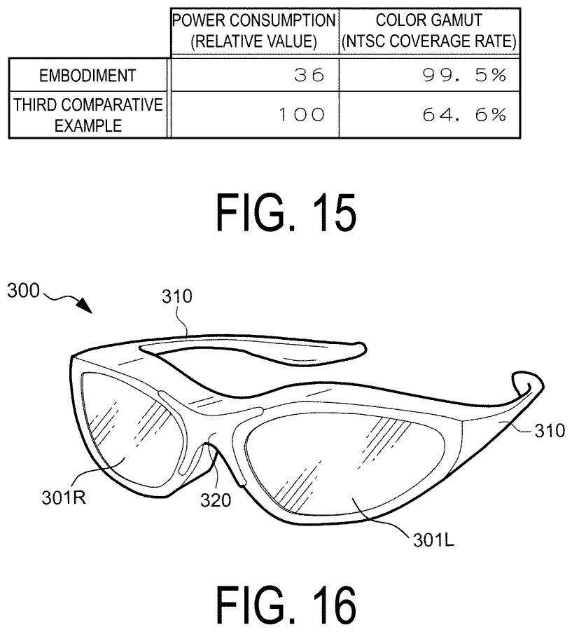

FIG. 14 is a view illustrating dimensions of the respective portions in the present embodiment and the third comparative example, and FIG. 15 is a view illustrating power consumption and a color gamut coverage in the present embodiment and the third comparative example. In the third comparative example, the optical adjustment layer 70 is not provided, and hence light extraction efficiency is degraded. Thus, in the third comparative example, power consumption is increased, and the reproducible color gamut is narrowed as compared to the present embodiment.

In contrast, in the present embodiment, light extraction efficiency is improved. Thus, low power consumption can be achieved, and the reproducible color gamut expands.

In the present embodiment, titanium nitride used for the pixel electrodes 131R, 131G, and 131B is a conductive layer used as barrier metal in a semiconductor manufacturing process. Thus, there is no risk of heavy metal contamination in the semiconductor manufacturing process. Thus, when titanium nitride is used for the pixel electrodes 131R, 131G, and 131B, no special precautions are required in the semiconductor manufacturing process.

In the process of manufacturing the electro-optical device 10, the process of forming the pixel separation layer 134 and forming the openings Ap_R, Ap_G, and Ap_B corresponds to the semiconductor manufacturing process, and the process thereafter is formation of the organic layer 132, for which another manufacturing device is used. Thus, when a substrate after formation of the openings Ap_R, Ap_G, and Ap_B is transferred to the manufacturing device for forming the organic layer 132, the substrate is exposed to an atmosphere. However, in the present embodiment, the pixel electrodes 131R, 131G, and 131B that open in the openings Ap_R, Ap_G, and Ap_B are nitride films, and hence generation of a natural oxide film is limited. Thus, transfer to the manufacturing device for forming the organic layer 132 can be achieved while maintaining a state in which the contact resistance at the surfaces of the pixel electrodes 131R, 131G, and 131B is low.

Injection of holes from the pixel electrodes 131R, 131G, and 131B being conductive titanium nitride into the organic layer 132 can be achieved by a material with strong electrical attraction. Examples of the material include HAT-CN (2, 3, 6, 7, 10, 11-Hexacyano-1, 4, 5, 8, 9, 12-Hexaazatriphenylene). When the hole injection layer 1321 is configured by an organic thin film containing a cyanide group represented by HAT-CN, hole injection is facilitated even from titanium nitride that does not particularly have high work function.

In the present embodiment, the OLED is used as an example of the light emitting element, but the present disclosure is not limited thereto, and an inorganic EL element using an inorganic material, or a PLED element may be used.

Next, an electronic apparatus to which the electro-optical device 10 according to the above-described embodiment is applied is described. The electro-optical device 10 is suitable for application with a small pixel and high definition display. Consequently, a head-mounted display is described as an example of the electronic apparatus.

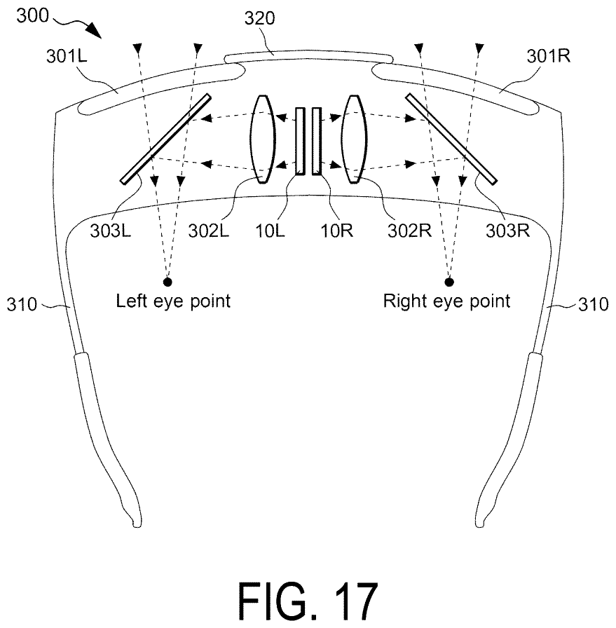

FIG. 16 is a view illustrating appearance of a head-mounted display, and FIG. 17 is a view illustrating an optical configuration of the head-mounted display.

First, as illustrated in FIG. 16, a head-mounted display 300 includes, in terms of appearance, temples 310, a bridge 320, and lenses 301L and 301R, similar to typical eye glasses. In addition, as illustrated in FIG. 17, in the head-mounted display 300, an electro-optical device 10L for a left eye and an electro-optical device 10R for a right eye are provided in the vicinity of the bridge 320 and on the back side (the lower side in the drawing) of the lenses 301L and 301R.

An image display surface of the electro-optical device 10L is arranged to be on the left side in FIG. 17. Thus, a display image by the electro-optical device 10L is output via an optical lens 302L in a 9-o'clock direction in the drawing. A half mirror 303L reflects the display image by the electro-optical device 10L in a 6-o'clock direction, while the half mirror 303L transmits light incident in a 12-o'clock direction. An image display surface of the electro-optical device 10R is arranged on the right side opposite to the electro-optical device 10L. Thereby, the display image by the electro-optical device 10R is output via the optical lens 302R in a 3-o'clock direction in the drawing. A half mirror 303R reflects the display image by the electro-optical device 10R in a 6-o'clock direction, while the half the mirror 303R transmits light incident in a 12-o'clock direction.

In this configuration, a wearer of the head-mounted display 300 can observe the display images by the electro-optical devices 10L and 10R in a see-through state in which the display image by the electro-optical devices 10L and 10R overlaps the outside.

Further, in the head-mounted display 300, in the images for both eyes with parallax, an image for the left eye is displayed on the electro-optical device 10L, and an image for the right eye is displayed on the electro-optical device 10R, and thus, it is possible to cause the wearer to sense the displayed images as an image having a depth or a three-dimensional effect.

In addition to the head-mounted display 300, the electronic apparatus including the electro-optical device 10 can be applied to an electronic viewing finder in a video camera, a lens-exchangeable digital camera, or the like, a mobile information terminal, a wristwatch display, a light valve for a projection type projector, and the like.

Preferred aspects of the present disclosure are understood from the above description, as follows. In the following, in order to facilitate understanding of each of the aspects, the reference signs of the drawings are provided in parentheses for convenience, but the present disclosure is not intended to be limited to the illustrated aspects.

An electro-optical device according to one aspect of the present disclosure includes a first reflection layer (62R) and a second reflection layer (62G) having light reflectivity and being adjacent to each other along a first direction in plan view, a first pixel electrode (131R) and a second pixel electrode (131G) being formed of a metal nitride and being adjacent to each other along the first direction (X direction) in plan view, a first optical adjustment layer (70) having an insulating property and optical transparency and being provided between the first reflection layer (62R) and the first pixel electrode (131R), a second optical adjustment layer (70) having an insulating property and optical transparency and being provided between the second reflection layer and the second pixel electrode, an insulating layer (134) opening in a first opening portion (Ap_R) with respect to the first pixel electrode (131R) in plan view and opening in a second portion (Ap_G) with respect to the second pixel electrode (131G) in plan view, a common electrode (133), and an organic layer (132) being provided between the common electrode (133), and the insulating layer (134), the first pixel electrode (131R), or the second pixel electrode (131G), and including a light emitting layer, wherein, in plan view, an end of ends of the first opening portion (Ap_R) that is adjacent to the second opening portion (Ap_G) is a first end (P₁), an end of ends of the first reflection layer (62R) that is adjacent to the second reflection layer (62G) is a second end (P₂), an end of ends of the first pixel electrode (131R) that is adjacent to the second pixel electrode (131G) is a third end (P₃), an end of ends of the second opening portion (Ap_G) that is adjacent to the first opening portion (Ap_R) is a fourth end (P₄), an end of ends of the second reflection layer (62G) that is adjacent to the first reflection layer (62R) is a fifth end (P₅), and an end of ends of the second pixel electrode (131G) that is adjacent to the first pixel electrode (131R) is a sixth end (P₆), the first end (P₁), the second end (P₂), and the third end (P₃) are positioned in the stated order along the first direction (X direction) from the first opening portion (Ap_R) to the second opening portion (Ap_G), and the fourth end (P₄), the fifth end (P₅), and the sixth end (P₆) are positioned in the stated order along the first direction (X direction) from the second opening portion (Ap_G) to the first opening portion (Ap_R). According to the first aspect, peripheral light emission can be reduced.

The electro-optical device (10) according to a specific aspect (second aspect) of the first aspect includes a third reflection layer (62R) having light reflectivity and being adjacent to the first reflection layer (62R) along a second direction (Y direction) intersecting with the first direction (X direction), and a third pixel electrode (131R) being formed of a metal nitride and being adjacent to the first pixel electrode (131R) along the second direction (Y direction) in plan view, wherein the first optical adjustment layer (70) is provided between the third reflection layer (62R) and the third pixel electrode (131R), the insulating layer (134) opens in a third opening portion (Ap_R) with respect to the third pixel electrode (131R) in plan view, the organic layer (132) is provided between the insulating layer (134) or the third pixel electrode (131R), in plan view, an end of ends the third opening portion (Ap_R) that is adjacent to the first opening portion (Ap_R) is a seventh end (P₇), an end of ends of the third reflection layer (62R) that is adjacent to the first reflection layer (62R) is an eighth end (P₈), and an end of ends of the third pixel electrode (131R) that is adjacent to the first pixel electrode (131R) is a ninth end (P₉), and the seventh end (P₇), the eighth end (P₈), and the ninth end (P₉) are positioned in the stated order along the second direction (Y direction) from the third opening portion (Ap_R) to the first opening portion (Ap_R).

In the electro-optical device (10) according to a specific aspect (third aspect) of the first aspect, in plan view, a width (L₂₃) between the second end (P₂) and the third end (P₃) along the first direction (X direction) is larger than a width (L₁₂) between the first end (P₁) and the second end (P₂).

In the electro-optical device (10) according to a specific aspect (fourth aspect) of the first aspect, in plan view, a width (L₂₃) between the second end (P₂) and the third end (P₃) along the first direction (X direction) is larger than a width (L₃₆) between the third end (P₃) and the sixth end (P₆).

In the electro-optical device (10) according to a specific aspect (fifth aspect) of the first aspect, the organic layer (132) contacts the first pixel electrode (131R) and the second pixel electrode (131G), and includes a hole injection layer (1321) being composed of HAT-CN.

In the electro-optical device (10) according to a specific aspect (sixth aspect) of the first aspect, the thickness of the first pixel electrode (131R) and the second pixel electrode (131G) is equal to or larger than 5 nm and smaller than 20 nm.

An electronic apparatus (300) according to a seventh aspect includes the electro-optical device (10) according to any one of aspects 1 to 6.

What is claimed is:

1. An electro-optical device comprising:
a first reflection layer and a second reflection layer having light reflectivity and being adjacent to each other along a first direction in plan view;
a first pixel electrode and a second pixel electrode being formed of a metal nitride and being adjacent to each other along the first direction in plan view;
a first optical adjustment layer having an insulating property and optical transparency and being provided between the first reflection layer and the first pixel electrode;
a second optical adjustment layer having an insulating property and optical transparency and being provided between the second reflection layer and the second pixel electrode;
an insulating layer opening in a first opening portion to the first pixel electrode in plan view and opening in a second portion to the second pixel electrode in plan view;
a common electrode; and
an organic layer being provided between the common electrode, and the insulating layer, the first pixel electrode, or the second pixel electrode, and including a light emitting layer, wherein
in plan view, an end of ends of the first opening portion that is adjacent to the second opening portion is a first end, an end of ends of the first reflection layer that is adjacent to the second reflection layer is a second end, an end of ends of the first pixel electrode that is adjacent to the second pixel electrode is a third end, an end of ends of the second opening portion that is adjacent to the first opening portion is a fourth end, an end of ends of the second reflection layer that is adjacent to the first reflection layer is a fifth end, and an end of ends of the second pixel electrode that is adjacent to the first pixel electrode is a sixth end,
the first end, the second end, and the third end are positioned in the stated order along the first direction from the first opening portion to the second opening portion, and
the fourth end, the fifth end, and the sixth end are positioned in the stated order along the first direction from the second opening portion to the first opening portion.

2. The electro-optical device according to claim 1, comprising:
a third reflection layer having light reflectivity and being adjacent to the first reflection layer along a second direction intersecting with the first direction in plan view; and
a third pixel electrode being formed of a metal nitride and being adjacent to the first pixel electrode along the second direction in plan view, wherein
the first optical adjustment layer is provided between the third reflection layer and the third pixel electrode,
the insulating layer opens in a third opening portion to the third pixel electrode in plan view,
the light emitting layer is provided between the insulating layer or the third pixel electrode,
in plan view, an end of ends the third opening portion that is adjacent to the first opening portion is a seventh end, an end of ends of the third reflection layer that is adjacent to the first reflection layer is an eighth end, and an end of ends of the third pixel electrode that is adjacent to the first pixel electrode is a ninth end, and
the seventh end, the eighth end, and the ninth end are positioned in the stated order along the second direction from the third opening portion to the first opening portion.

3. The electro-optical device according to claim 1, wherein
in plan view, a width between the second end and the third end along the first direction is larger than a width between the first end and the second end.

4. The electro-optical device according to claim 1, wherein
in plan view, a width between the second end and the third end along the first direction is larger than a width between the third end and the sixth end.

5. The electro-optical device according to claim 1, wherein
the organic layer contacts the first pixel electrode and the second pixel electrode, and includes a hole injection layer being composed of HAT-CN.

6. The electro-optical device according to claim 1, wherein
a thickness of the first pixel electrode and a thickness of the second pixel electrode are equal to or larger than 5 nm and smaller than 20 nm.

7. An electronic apparatus comprising the electro-optical device according to claim 1.
